(19) United States
(12) Patent Application Publication
(10) Pub. No.: US 2008/0296744 A1
(43) Pub. Date: Dec. 4, 2008

(54) Integrated Circuit

(75) Inventor: Nobuyuki Kurihara, Ota-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Kabushiki Kaisha Toshiba, Tokyo (JP)

(21) Appl. No.: 12/128,559

(22) Filed: May 28, 2008

(30) Foreign Application Priority Data
May 31, 2007 (JP) 2007-146032

(51) Int. Cl. H01L 23/552

(52) U.S. Cl. 257/659; 257/E23.114

(57) ABSTRACT

According to one embodiment, an integrated circuit includes an internal circuit and a resin layer which covers the internal circuit. A radio wave absorbing material is mixed in the resin layer.

### CROSS-REFERENCE TO RELATED APPLICATIONS

This application is based upon and claims the benefit of priority from Japanese Patent Application No. 2007-146032, filed May 31, 2007, the entire contents of which are incorporated herein by reference.

### BACKGROUND

1. Field

One embodiment of the present invention relates generally to an integrated circuit, and more particularly to an integrated circuit in which an internal circuit is covered with a resin.

2. Description of the Related Art

A countermeasure to unwanted direct radiation from an IC or the like is implemented, in usual cases, by using a material having radio wave absorption characteristics. In a high-speed process device, such as a CPU, thermal design is also important and a problem relating to heat is solved by using a heat-conductive sheet and a radiation plate.

With the recent trend of higher clock speeds, the thermal design and unwanted radiation design, above all, are inevitable challenges. In the prior art, there has been proposed a semiconductor IC containing substrate which is a multilayer substrate comprising a plurality of stacked resin layers, and which includes, at least as one layer, a resin layer in which ferrite or metallic magnetic powder is mixed (It is disclosed by, for example, Jpn. Pat. Appln. KOKAI Publication No. 2006-19340).

Recently, there is known a heat-conductive sheet in which a radio wave absorbing material is mixed, but this requires an additional cost. In addition, since this heat-conductive sheet is classified as goods which are subjected to export restrictions, it is also difficult to procure materials for mass-production. Besides, the effect of a member for coping with unwanted radiation is greater as the member is disposed closer to a circuit which is a generation source of noise.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1A is an exemplary view for describing an example of a shield cover of an integrated circuit according to an embodiment of the invention;

FIG. 1B is an exemplary view for describing an example of a shield frame of the integrated circuit according to the embodiment of the invention;

FIG. 1C is an exemplary view for describing an example of a printed circuit board of the integrated circuit according to the embodiment of the invention;

FIG. 2 is an exemplary view that schematically shows an example of the structure of the integrated circuit according to the embodiment; and

FIG. 3 is an exemplary view that schematically shows an example of the cross section of the integrated circuit in the embodiment.

### DETAILED DESCRIPTION

Various embodiments according to the invention will be described hereinafter with reference to the accompanying drawings. In general, according to one embodiment of the invention, there is provided an integrated circuit comprising: an internal circuit; and a resin layer which covers the internal circuit, wherein a radio wave absorbing material is mixed in the resin layer.

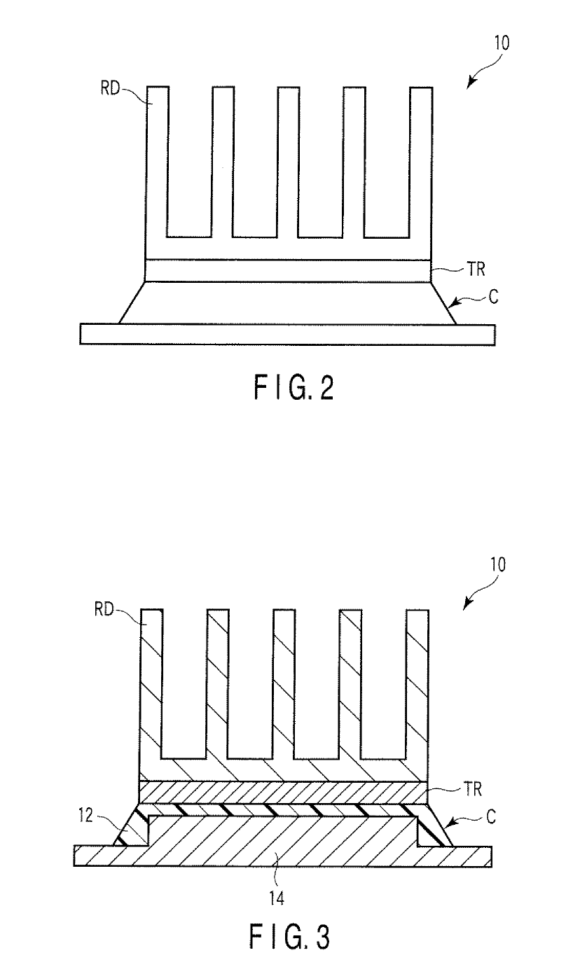

As shown in FIG. 2, for example, an integrated circuit 10 according to an embodiment of the invention includes a circuit section C, a heat-conductive sheet TR which is disposed on the circuit section C, and a heat-radiation plate RD which is disposed on the heat-conductive sheet TR.

As shown in FIG. 3, the circuit section C includes an internal circuit 14 and a resin layer 12 which covers the internal circuit 14. Ferrite is mixed in the resin layer 12 as a radio wave absorbing material.

The heat-conductive sheet TR conducts heat, which is produced from the circuit section C, to the heat-radiation plate RD that is disposed on the heat-conductive sheet TR. Accordingly, since the heat-conductive sheet TR is disposed between the circuit section C and the heat-radiation plate RD, the heat that is produced from the circuit section C can effectively be radiated.

As has been described above, according to the integrated circuit 10 of the present embodiment, radio waves, which are emitted from the internal circuit 14 that is a generation source of radio waves, are absorbed by the ferrite that is mixed in the resin layer 12 which is disposed closest to the internal circuit 14. Thus, the generation of noise due to radio waves, which are emitted from the internal circuit 14, can be suppressed.

Therefore, this embodiment can provide an integrated circuit which realizes low-cost unwanted radiation design.

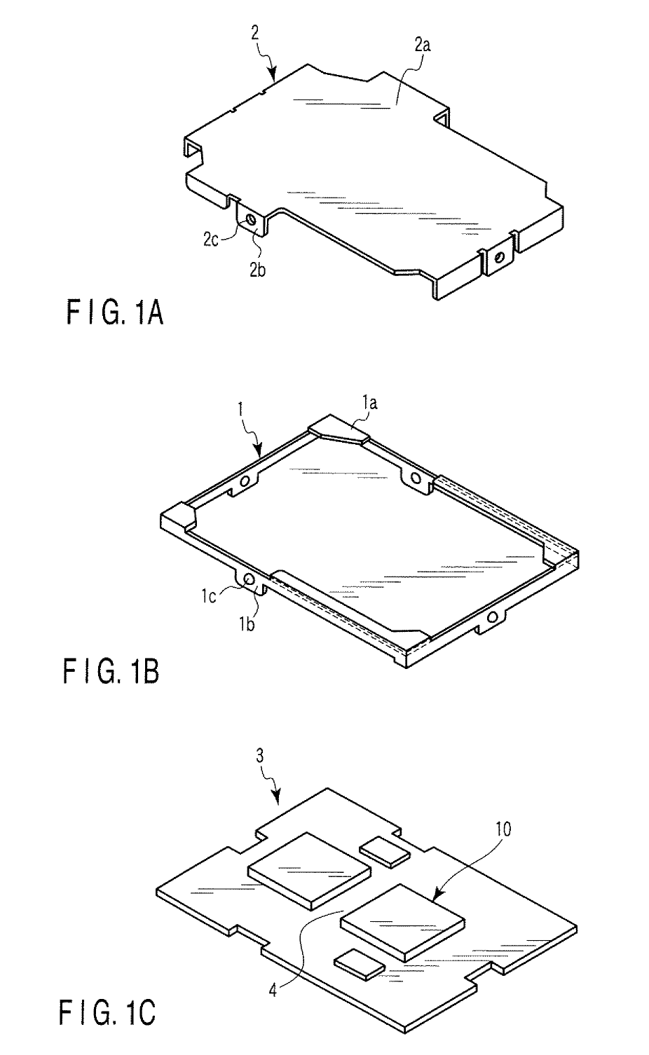

Next, an example of application of the integrated circuit 10 according to the present embodiment is described. As shown in FIG. 1A to FIG. 1C, the integrated circuit according to the present embodiment is applicable to a radio-frequency circuit module device which is represented by mobile equipment, for instance, a mobile terminal such as a mobile phone or a personal computer, or a tuner which is built in a PC card.

A circuit module device shown in FIG. 1A to FIG. 1C comprises a shield frame 1, a shield cover 2 which is engaged with the shield frame 1, and a printed circuit board 3 which is fixed at a predetermined position of the shield frame 1. The integrated circuit 10 according to the present embodiment is mounted, as a tuner IC or a demodulation IC, on a board 4 of the printed circuit board (to-be-supported member) 3. The shield frame 1 and shield cover 2 constitute a shield case.

The shield frame 1 is formed as a frame body, which has a rectangular shape as a whole, by punching out a central portion of an electrically-conductive planar shield plate by, e.g. press working, and bending peripheral parts thereof at about 90°. Planar flange portions 1a are formed at the four corners of the frame body. A protrusion portion 1b is provided at a substantially central position of each of the bent parts of the shield frame 1, and a projection 1c is formed on the protrusion portion 1b.

On the other hand, the shield cover 2 is configured to be engaged with the shield frame 1 so as to cover the surface of the shield frame 1. When the shield cover 2 and the shield frame 1 are combined, the shield cover 2 is configured to have a substantially equal height to the height of the shield frame 1, so that the shield cover 2 may not project from the shield frame 1 in the thickness direction of the shield frame 1. Specifically, the shield cover 2 has a planar portion 2a which covers the punched-out area of the shield frame 1 so that the surface of the shield frame 1 becomes flush with the surface of the shield cover 2 in a planar direction parallel to the planar direction of the circuit board 3. Those parts of the shield cover 2, which correspond to the flange portions 1a, are removed. In addition, those parts of the shield cover 2, which correspond to the protrusion portions 1b of the shield frame 1, are bent by, e.g. press working, at about 90°, and thereby protrusion portions 2b are formed on sides of the shield cover 2. Each of the protrusion portions 2b is provided with a recess or a hole.

As has been described above, by using the integrated circuit 10 in the radio-frequency circuit module device, radio waves, which are emitted from the internal circuit 14 that is the generation source of radio waves, are absorbed by the ferrite mixed in the resin layer 12 that is disposed closest to the internal circuit 14. Therefore, the influence of noise due to the integrated circuit 10 can be suppressed, and the module device with high performance can be provided.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An integrated circuit comprising:
an internal circuit; and
a resin layer which covers the internal circuit,
wherein a radio wave absorbing material is mixed in the resin layer.

2. The integrated circuit according to claim 1, wherein the radio wave absorbing material is ferrite.

3. The integrated circuit according to claim 1, further comprising:
a heat-conductive sheet which is disposed on the resin layer; and
a heat-radiation plate which is disposed on the heat-conductive sheet.
